(19) United States
(12) Patent Application Publication
(10) Pub. No.: US 2025/0217566 A1
(43) Pub. Date: Jul. 3, 2025

(54) SYSTEM AND METHOD UTILIZING MACHINE LEARNING (ML) FOR ANALOG AND MIXED-SIGNAL CIRCUIT LAYOUT SYNTHESIS

(71) Applicants: YUAN-JU CHAO, CUPERTINO, CA (US); WAN-TING CHOU, ZHUBEI CITY (TW)

(72) Inventors: YUAN-JU CHAO, CUPERTINO, CA (US); WAN-TING CHOU, ZHUBEI CITY (TW)

(21) Appl. No.: 18/397,692

(22) Filed: Dec. 27, 2023

(51) Int. Cl. G06F 30/367; G06F 30/38

(52) U.S. Cl. CPC G06F 30/367; G06F 30/38

(57) ABSTRACT

The present invention discloses an algorithm for the realization of analog and mixed-signal circuit layout leveraging Machine Learning (ML). The algorithm is structured with Input Parameters, pre-trained Databases and Deep Learning Engines. Deep Learning Engines integrate with the specified Parameters and Databases to produce optimal analog layout realizations. These generated realizations undergo feedback into the Databases, refining the algorithm's efficiency and accuracy for subsequent runs. The algorithm ensures layout signal integrity, concurrently minimizing human error, layout iteration cycles and development time.

### BACKGROUND

The invention relates analog and mixed-signal layout synthesis.

The burgeoning world of electronic devices is driving the need for fast and efficient production of analog and mixed-signal circuits. These circuits are commonly used in several applications such as mobile devices, data communication systems, and many others due to their ability to process both digital and analog signals, which is a key element in interfacing real-world and digital information.

An integral aspect of the circuit design process is the layout design, which is a graphical representation of the arrangement of circuit elements in a prescribed formation. It directly influences the functionality and performance of the designed circuits. The conventional layout design methods generally necessitate time-consuming manual efforts and involve a high risk of human errors leading to design flaws and under-optimized solutions. In addition, the complexity associated with the layout design process is accelerating with the miniaturization of semiconductor technology.

Unlike digital circuitry, analog layout requires a customized approach to accommodate intricate factors influencing signal integrity. These factors encompass a spectrum of considerations, including but not limited to matching, symmetry, layout-dependent effects, current density, guardring, parasitic resistance, parasitic capacitance. The intricacies of achieving an optimal analog layout demand an iterative collaboration between circuit designer and layout professionals, contributing to a unique set of challenges.

The implementation of analog and mixed-signal circuit layouts is inherently labor-intensive, reliant on high levels of skill, and time-consuming efforts. Moreover, the susceptibility to human error introduces additional complexity to the process.

### SUMMARY

In one aspect, systems and methods are disclosed for analog and mixed-signal circuit layout synthesis employing Machine Learning (ML), emphasizing layout integrity enhancement. The systematic algorithm incorporates five sequential procedures:
1. Technology Sift
2. Templating
3. Deep Learning
4. Optimization
5. Yield Analysis

In another aspect, a system and method for synthesizing analog or mixed-signal circuit layouts are disclosed. The system utilizes a combination of predefined technology and template databases to select specific fabrication technology and circuit templates. The system also employs a pre-trained deep learning engine to synthesize the circuit layout based on design specifications and analog standard cell and analog modules. An optimizer code refines the circuit layout based on user-defined parameters and a simulation code conducts a yield analysis on the layout. Final layout decisions consider factors such as yield, performance, or power, and the updated layout is fed back to the existing databases for ongoing improvement. The method involves a similar process including technology and template selection, deep learning synthesis, optimization, yield analysis, layout generation, and iterative feedback for refining efficiency and accuracy. The synthesized layout is also subjected to various rule checks including Design Rule Check (DRC), Layout versus Schematic (LVS), Electrical Rule Check (ERC), Antenna Rule Check (ANT), and Electrostatic Discharge check (ESD).

Advantages of the above system may include one or more of the following. The present invention introduces an algorithm utilizing Machine Learning (ML) for the synthesis of analog circuit layout. The proposed system employs advanced Machine Learning (ML) techniques based on design specifications and predefined databases to automatically generate and optimize circuit layout. This innovative approach significantly enhances the efficiency and effectiveness of analog circuit layout synthesis, minimizing manual efforts and iteration cycles while ensuring signal integrity. Moreover, the algorithm serves to mitigate the risk of human error.

These procedures represent an advancement in analog and mixed-signal circuit layout synthesis, offering a streamlined and efficient process to ensure both reliability and adherence to project requirements.

A more complete appreciation of the present invention and its improvements can be obtained by reference to the accompanying drawings, which are briefly summarized below, to the following detailed description of illustrative embodiments of the invention, and to the appended claims.

### BRIEF DESCRIPTION OF THE DRAWINGS

The accompanying drawings illustrate the detailed procedures of Machine Learning (ML) synthesized analog layout, providing a visual comprehension of the implementation of the disclosed invention.

FIG. 1 depicts the overview diagram of the Machine Learning (ML) algorithm for analog layout synthesis, highlighting its principal three components: Input Parameters, Trained Databases and Machine Learning Engines.

FIG. 2 shows a more detailed structure of the algorithm and illustrates the inter-connection between Input Parameters, Trained Databases and Machine Learning Engines.

FIG. 3 illustrates the comprehensive algorithm procedures of analog layout realization utilizing Machine Learning (ML).

FIG. 4 illustrates the Training Cycle of Deep Learning Engine.

FIG. 5 illustrates the detailed database structure of Analog Standard Database and Analog Module Database as referenced in FIG. 3.

FIG. 6 illustrates the detailed parameter metrics of Layout Parameters as depicted in FIG. 3.

### DETAILED DESCRIPTION

The detailed description provides a comprehensive overview of the Machine Learning (ML)-synthesized analog layout procedures. Each procedure step is designed to fulfil specific requirements, ensuring a coherent and effective design process. The system leverages Machine Learning (ML) to streamline and optimize the analog layout synthesis process. This approach reduces manual efforts, iterations cycles, and minimize human error, enhancing the overall efficiency and effectiveness of analog and mixed-signal circuit layout synthesis.

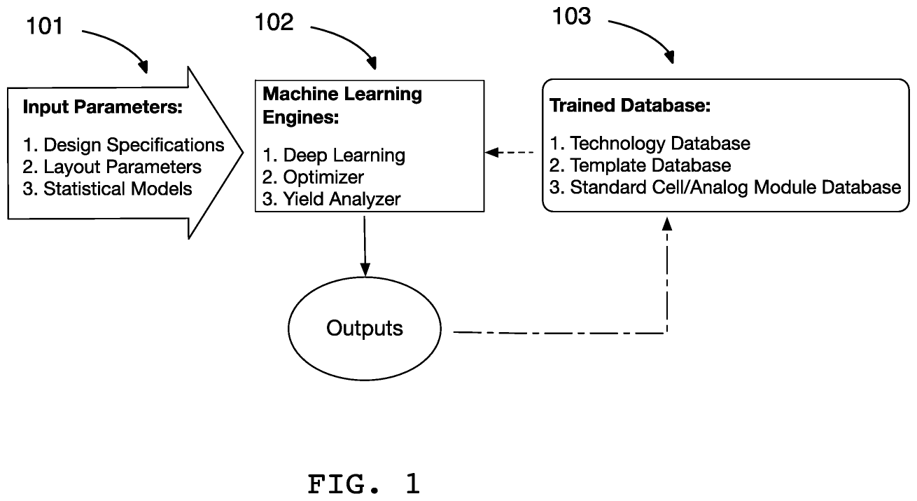

FIG. 1 depicts the overview diagram of the Machine Learning (ML) algorithm for analog layout synthesis, highlighting its principal three components: Input Parameters, Trained Databases and Machine Learning Engines. The systematic algorithm is structured with Input Parameters 101, Machine Learning (ML) Engines 102 and Trained Databases 103. The Machine Learning (ML) Engines integrate with the specified Input Parameters and Trained Databases to produce optimal analog layout realizations. These generated realizations are systematically fed back into the Databases, refining the algorithm's efficiency and accuracy for subsequent iterations.

The Input Parameters consists of three essential components: Design Specifications, Layout Parameters and Statistical Models. These elements collectively define the criteria and characteristics guiding Machine Learning (ML) algorithm during analog layout synthesis.

The Trained Databases comprise three components: Technology Database, Template Database and Standard Cell/Analog Module Database. This repository stores critical information and templates necessary for the Machine Learning (ML) algorithm to synthesis analog layout effectively with required accuracy.

The Machine Learning (ML) Engines consist of three pivotal components: Deep Learning, Optimizer and Yield Analyzer. These engines process the specified parameters and incorporates with pre-trained database to provide optimal synthesized results. The outputs generated by the Engines contribute new information, which is systematically fed back to the Trained Database. The iterative process enriches and refines the database, consequently enhancing the overall efficiency and effectiveness of the algorithm.

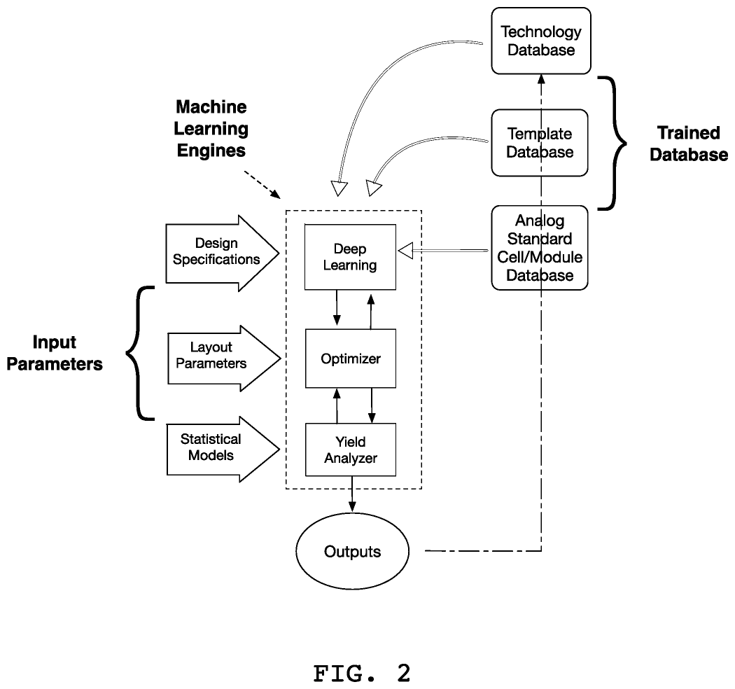

FIG. 2 shows a more detailed structure of the algorithm and illustrates the inter-connection between Input Parameters, Trained Databases and Machine Learning Engines. The Machine Learning Engines are systematically organized into three sequential components: Deep Learning, Optimizer and Yield Analyzer. Each of these engines is fed with specific Input Parameters, namely Design Specifications, Layout Parameters and Statistical Models, aligning with their designated functionalities.

The operational process begins as the Machine Learning Engines assimilate the Input Parameters, accessing the pre-trained database to synthesis analog layout realization. Importantly, the three engines, Deep Learning, Optimizer and Yield Analyzer engage in iteratively interaction and collaboration. The iterative process aims to achieve an optimal outcome, emphasizing the dynamic and cooperative nature of the algorithm in refining and enhancing analog layout synthesis results over successive iterations.

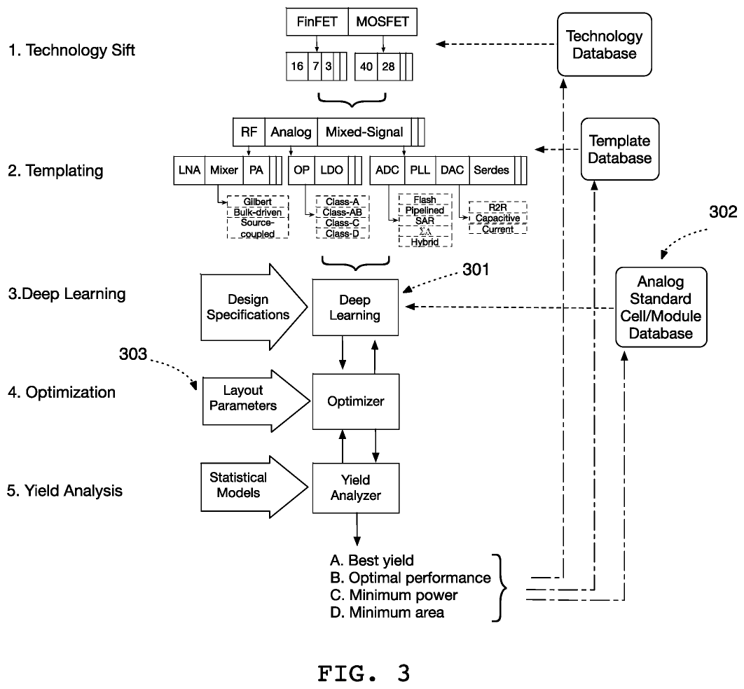

FIG. 3 illustrates the comprehensive algorithm procedures of analog layout realization utilizing Machine Learning (ML). The algorithm incorporates five sequential procedures:
Technology Sift, Templating, Machine Learning, Optimization and Yield Analysis. Each procedure of the algorithm is designed to systematically ensure the efficiency and precision of the analog layout synthesis.

Technology Sift: This phase begins with the selection of the technology, choosing between FinFET or MOSFET processes. The subsequent decision involves specifying the process node, such as 16 nm/7 nm/3 nm, etc., under FinFET, or 40 nm/28 nm, etc., under MOSFET. These critical choices lay the foundation for subsequent procedures, ensuring alignment with the desired technology parameters. The selections of technology are sourced from Technology Database.

Templating: In this stage, the function of analog circuit is determined based on predefined templates. The process involves the initial selection of either Radio Frequency (RF), Analog, or Mixed-Signal category. Subsequently, a more specific circuit function is chosen, followed by the selection of the appropriate architecture. For instance, RF category consists of LNA, Mixer and PA etc. ADC architecture can be Flash, Pipelined, SAR, Sigma-Delta (ΣΔ), or hybrid. All the templates are sourced from Template Database.

Deep Learning: In this stage, the algorithm inputs design specifications, analog standard cells, and analog modules, to the Deep Learning engine 301. The Deep Learning engine then synthesize an analog layout realization, in accordance with the specified requirements and parameters. Analog standard cells encompass basic gates such as switches, buffers in various sizes, while Analog modules comprises functional blocks such as current mirrors, comparators. Analog standard cells and Analog models originate from Analog Standard Cell/Module Database 302.

Optimization: In this stage, the Layout Parameters 303, including matching, symmetry, current density, noise coupling, dummy insertion, guardring insertion, parasitic resistance, parasitic capacitance, area margin etc., are supplied for the Optimizer to refine and achieve an optimal realization.

Yield Analysis: Statistical models, including Monte-Carlo, mismatch, Design for Manufacture (DFM) model, aging and self-heating models, are integrated and provided to Yield Analyzer. Yield Analyzer collaborates with Deep Learning engine and Optimizer iteratively to derive the final layout realizations. The layout realizations present a range of options, including best yield, optimal performance, minimum power consumption and minimum area results.

The algorithm feeds back the final layout realizations generated by the Yield Analyzer into three databases: Technology Database, Template Database and Standard Cell/Module Database. This iterative process enhances the databases, contributing to improved efficiency in subsequent synthesis endeavors.

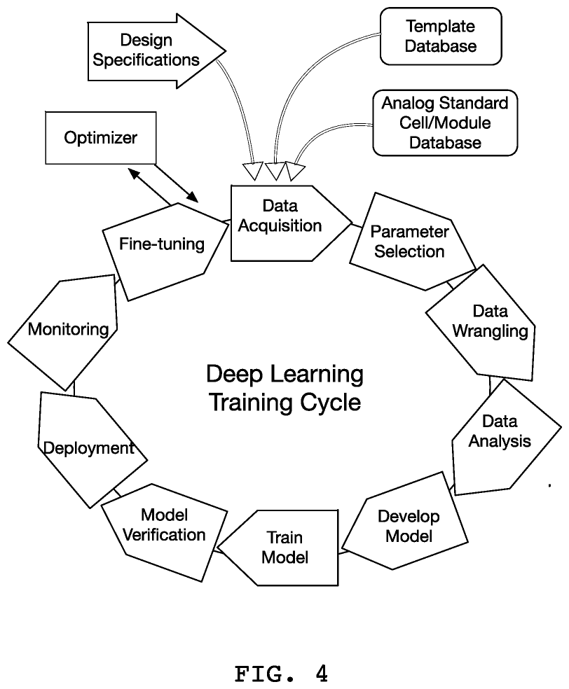

FIG. 4 illustrates the Training Cycle of Deep Learning Engine 301 in FIG. 3. The Training Cycle of Deep Learning Engine is a comprehensive and systematic process comprising ten essential steps designed to facilitate the effective training of Deep Learning model, particularly focused on analog layout synthesis. The objective of this process is to ensure the accuracy, adaptability, and practical applicability of the resulting model. Each step is further explained below:

1. Data Acquisition: This initial step involves collecting the necessary data for training the Deep Learning model. The sources of this data pool include Design Specifications, Template Database and Analog Standard Cell/Module Database. The quality and quantity of the data significantly influence the model's performance.

2. Parameter Selection: During this step, relevant parameters for the Deep Learning model are carefully chosen. These parameters play a crucial role in shaping the model's behavior and learning capabilities.

3. Data Wrangling: The acquired data may undergo preprocessing and cleaning to ensure consistency and relevance. Data Wrangling prepares the data for effective utilization in the subsequent steps.

4. Data Analysis: An in-depth analysis of the prepared data is conducted to gain insights into patterns, trends, and relationships. This analysis informs the model development process.

5. Develop Model: In this step, the actual Deep Learning model is constructed based on the selected parameters and insights gained from the data analysis. The architecture and structure of the model are formulated.

6. Train Model: The developed model is trained using the prepared data. This involves exposing the model to the datasheet, allowing it to learn and adjust its parameters iteratively.

7. Model Verification: After training, the model's performance is thoroughly verified. This step ensures that the model accurately captures the patterns within the data and generalizes well to new, unseen data.

8. Deployment: Once the model passes verification, it is deployed for practical application. Deployment involves integrating the model into the intended system or environment.

9. Monitoring: Continuous monitoring is crucial to assess the model's performance in real-world scenarios. Monitoring allows for the identification of potential issues and the collection of additional data for model improvement.

10. Fine-tuning: Based on the insights gained through monitoring, the model can be further fine-tuned to enhance its performance. This iterative refine process contributes to maintaining the model's relevance over time. At the conclusion of the fine-tuning step, the refined result is handed over to the Optimizer. The Optimizer serves as the second engine in the framework of Machine Learning Engines.

In summary, the Training Cycle of Deep Learning is a systematic and iterative process design to create a robust and effective model for analog layout synthesis. Each step plays a vital role in ensuring the algorithm's accuracy, adaptability, and practical applicability.

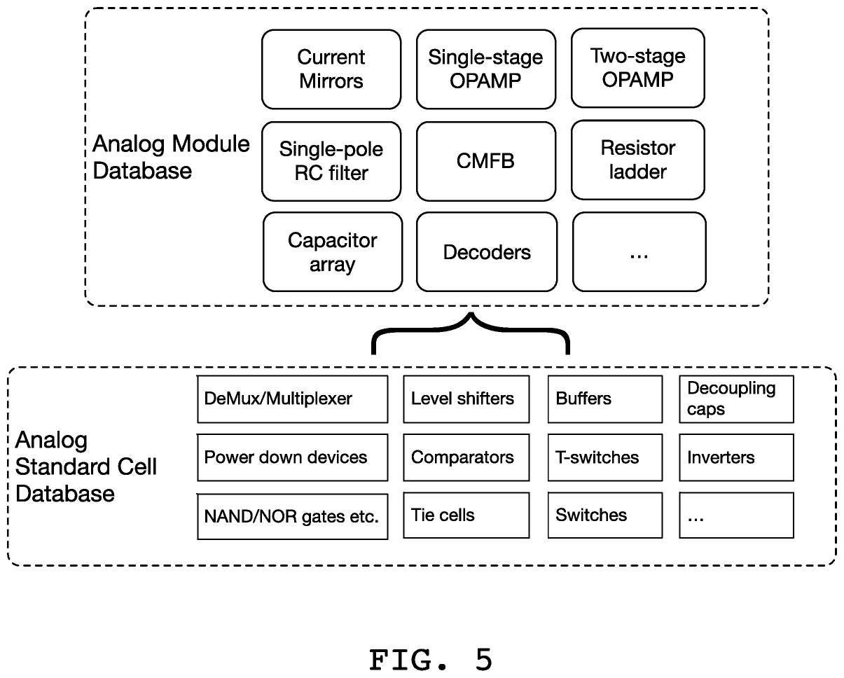

FIG. 5 outlines the detailed contents of Analog standard database and Analog Module database 302 as depicted in FIG. 3. It comprises two Database: Analog Standard Cell Database and Analog Module Database. Analog Standard Cell Database consists of fundamental cells like Level shifters, Comparators, DeMux/Mutiplexer, Power down devices, NAND/NOR gates, Buffers, Switches, Tie cell and Decoupling caps among others. Analog Module Database utilizes Analog Standard cells as foundation and constructs more complex circuitry, including but not limited to Current Mirrors, Single-stage amplifier (OPAMP), Two-stage OPAMP, Single-pole RC filter, Common-mode feedback (CMFB), Decoders, Resistor ladder, Capacitor array and other components.

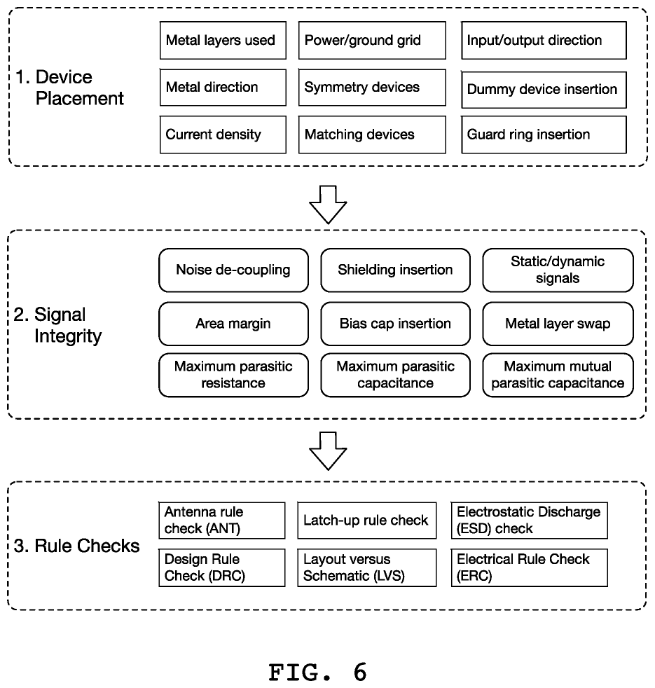

FIG. 6 details the contents of Layout Parameters 303 as shown in FIG. 3. It consists of three steps: Device Placement, Signal Integrity and Rule checks. The initial step, Device Placement paraments, includes aspects such as Metal layers direction, input/output direction, power/ground grid, current density, symmetry devices, matching devices, Dummy device insertion, Guard ring insertion among others. After establishing the placement of the devices and power/ground elements, the second step, Signal Integrity, initiates the connection of signals. In the second step, paraments includes Area margin, static/dynamic signals, noise de-coupling, shielding insertion, Bias cap insertion, Maximum parasitic resistance, Maximum parasitic capacitance, Maximum mutual parasitic capacitance among other factors.

In the third step, essential rule checks are conducted, including Design Rule Check (DRC), Layout versus Schematic (LVS), Electrical Rule Check (ERC), Antenna Rule Check (ANT), Electrostatic Discharge check (ESD) and Latch-up rule check.

As stated above, the Machine Learning algorithm begins with selecting a pre-defined technology during the Technology Sift procedure. This ensures the application of the correct technology, considering that each technology has distinct rules, leading to varied layout implementation.

The subsequent procedure in the algorithm, Templating, involves utilizing existing circuit template from the Template Database. Each template serves different functionalities. The layout consideration for a Phase-Locked Loop (PLL) circuit and Analog-to-Digital Converter (ADC) circuit differ significantly due to distinct circuitry characteristics. The use of a predefined template ensures efficient convergence during the synthesis process.

In the third procedure of the algorithm, Deep Learning, the engine has been trained on numerous functional circuitries and associated layout implementations. When Deep Learning engine receives a request from Design Specifications, it accesses templates and Analog standard Cell/Analog Modules to starts synthesizing based on its trained database, delivering a layout realization to the Optimizer engine.

In the fourth procedure of the algorithm, Optimizer, the engine takes user-defined Layout Parameter and apply optimization on the result obtained from Machine Learning engine. The Layout Parameters encompass three detailed steps: Device Placement, Signal Integrity and Rule Checks. Device Placement paraments include aspects such as Metal layers direction, input/output direction, power/ground grid, current density, symmetry devices, matching devices, Dummy device insertion, Guard ring insertion among others. Signal Integrity step paraments include Area margin, static/dynamic signals, noise de-coupling, shielding insertion, Bias cap insertion, Maximum parasitic resistance, Maximum parasitic capacitance, Maximum mutual parasitic capacitance among other factors. The Rule Checks step parameters include Design Rule Check (DRC), Layout versus Schematic (LVS), Electrical Rule Check (ERC), Antenna Rule Check (ANT), Electrostatic Discharge check (ESD) and Latch-up rule check.

In the fifth procedure of the algorithm, Yield Analyzer, the engine employs Statistical Models to simulate the analog realization. The Statistical Models include Monte-Carlo, mismatch model, Design for Manufacture (DFM) model, aging and self-heating models. The Yield Analyzer engine interacts with Deep Learning and Optimizer while simulating through the statistical models to generate a range of realization options, including best yield, optimal performance, minimum power consumption and minimum area results.

These four realization options are then delivered back to Three Databases: Technology Database, Template Database and Analog Standard Cell/Module Database. This iterative process enhances the algorithm's efficiency and accuracy through the enriched databases.

One embodiment relates to a method for selecting a pre-defined technology and pre-defined circuit topology, wherein the method identifying the most probable circuit characteristic from existing technology and templates. The process encompasses distinguishing between FinFET and MOSFET technologies, while the circuit characteristics include but not limited to Radio Frequency (RF), Analog, or Mixed-Signal categories.

Another embodiment introduces the feature of employing Deep Learning engine for the analog layout synthesis. The Deep Learning engine consider Design Specifications, pre-defined technology and templates, along with data from Analog Standard Cell/Analog Module database, to commence synthesis based on the algorithm's trained data. Furthermore, the Deep Learning engine couples and collaborates with Optimizer and Yield Analyzer to generate optimal analog layout realizations.

Yet another embodiment pertains to a system and methodology for analog layout synthesis optimization. Numerous parameters are specified for iterative refinement, including but not limited to area margin, maximum parasitic capacitance, maximum parasitic resistance, and maximum mutual capacitance. These parameters collectively form a procedural structure that allows for consistent recalibration and optimization of the electronic layout. The iterative refinement process enables the system to reach optimal reconciliation between constraints, leading to improved performance and thus, increasing the robustness of the electronic layout.

Further, one embodiment recognizes the necessary interaction among the Deep Learning engine, Optimizer and Yield Analyzer. If the Optimizer fails to achieve a satisfactory result given Design specification, Layout Parameters and statistical models, implying that the requirements are excessively stringent, Deep Learning engine, Optimizer and Yield Analyzer iteratively collaborate to derive an optimal solution.

Another important aspect of the invented method is the final outputs of Yield Analyzer provides a spectrum of options, including but not limited to the best yield, optimal performance, minimum power consumption and minimum area results. User can evaluate these metrics to ascertain the most fitting option based on their system requirements.

One embodiment establishes a feedback loop, wherein the Yield Analyzer sends resulted data to Technology Database, Template Database and Analog Standard Cell/Module Database. This iterative process contributes to the continuous improvement of the algorithm's efficiency and accuracy with each cycle.

In one embodiment, the method focuses on minimizing the efforts involved in analog layout realization and reducing human errors. The algorithm synthesis the layout implementation using existing templates and databases, ensuring the synthesized layout meets design specifications and passes all required rule checks.

The method and apparatus for analog and mixed-signal circuit layout generation employing Machine Learning (ML) present a systematic approach to address the challenges associated with analog layout. The algorithm consists of Input Parameters, pre-Trained Database and Machine Learning Engines. Parameters and Databases are coupled to Machine Learning Engines to generate outputs. The outputs are then fed back into three Databases to improve the efficiency. The synthesized layout implementation meets user-defined signal integrity requirements, attains optimal yield, and concurrently minimizes overall layout development time and iteration effort. Furthermore, the algorithm's database is enriched, leading to enhanced efficiency and accuracy with each run. Importantly, the algorithm effectively minimizes human error associated with analog layout.

The described system improves computer performance as follows:
Pre-defined Fabrication Technology Database: By categorizing technologies like FinFET or MOSFET, this database provides a foundation for selecting the most suitable technology for a given design. This leads to improvements in efficiency and performance of the final chip, as different technologies have varying characteristics in terms of power consumption, speed, and size. Technology Selection Code: This allows for automated, optimized selection of the appropriate technology based on specific design requirements. This automation improves the speed and accuracy of the design process, leading to more efficient use of computing resources.
Pre-defined Template Database: Having a variety of templates for different analog circuit functionalities speeds up the design process by providing starting points that are already optimized for certain tasks. This enhances computational efficiency by reducing the time and resources needed for design from scratch.
Templating Code: Automates the process of selecting and adapting circuit templates, which leads to more efficient design processes and better optimization of circuit layouts for specific applications.
Deep Learning Engine for Layout Synthesis: The use of a pre-trained deep learning engine to synthesize circuit layouts from specifications is a significant improvement in computational techniques. This approach optimizes layouts in ways that might be non-obvious to human designers, leading to designs that are more efficient, consume less power, or offer higher performance.
Optimizer Code for Layout Refinement: This code can make iterative improvements to the circuit layout, optimizing for user-defined parameters such as size, power consumption, or performance. This optimization process is used for enhancing the overall efficiency and effectiveness of the design. Yield Analysis Simulation Code: Simulating yield analysis using statistical models helps in predicting manufacturing defects and their impact on the overall production process. This leads to more reliable and efficient manufacturing processes, and by extension, better-performing chips.
Layout Generator Considering Yield, Performance, or Power: By generating layouts with a focus on these critical factors, the system ensures that the final designs are optimized not just for functionality but also for real-world performance parameters.
Feedback Loop to Improve Databases and Modules: The system's ability to feed the layout data back into the technology, template, and module databases for future reference improves the efficiency and accuracy of subsequent designs. This continuous improvement cycle improves performance of computer-aided design systems.

Overall, the foregoing leads to more efficient use of computational resources, faster design cycles, and the production of chips that are more efficient, reliable, and tailored to specific needs. These are concrete improvements in technology demonstrating a specific, beneficial application of computer technology.

One embodiment includes a pre-defined fabrication technology database primarily categorized by FinFET or MOSFET. It contains extensive information about different existing technologies used in the fabrication of analog or mixed-signal circuits. This information can be useful in determining the technology type for the circuit layout synthesis.

Additionally, it includes a code for selecting a specific technology from the pre-defined technology database. This part of one embodiment determines the appropriate technology to be used based on the requirements and constraints of the layout project to be carried out.

Further, one embodiment includes a pre-defined template database which is categorized by various analog circuitry functionality. This serves as a compendium of different practical and efficient layout designs and structures. The template database saves considerable time in the initial phases of the layout design by providing pre-structured analog circuitry modules.

One embodiment also carries a code for templating a specific circuit template from the pre-defined template database. This functional aspect is responsible for extracting a relevant template design based on the desired circuit functionality.

One embodiment encompasses in its architecture a pre-trained deep learning engine to synthesize the analog or mixed-signal circuit layout based on existing design specifications and analog standard cell and analog modules. The deep learning engine uses Machine Learning algorithms to generate optimized and efficient layout designs.

An optimizer code is incorporated into the system to further check and refine the analog or mixed-signal circuit layout given user-defined layout parameters. The optimizer aids in fine-tuning the design to fulfill the exact requirements set by the layout designers.

The system includes code for performing a yield analysis for the analog or mixed-signal circuit layout using one or more statistical models. This part of the system also feeds the synthesized analog or mixed-signal circuit layout back to the technology database, template database, and analog standard cell module database to improve layout efficiency and accuracy over time. This iterative process leads to an ever-improving system that grows more effective with each layout project it accomplishes.

In one embodiment, the technology selection pertains to a FinFET (Fin Field-Effect Transistor) process or a MOSFET (Metal-Oxide-Semiconductor Field-Effect Transistor) process. The system includes code for selecting the specific technology whereby it first selects either a FinFET or a MOSFET process flavor depending on the application required. The FinFET is selected when an application requires superior performance and lower power consumption, and the MOSFET is chosen when cost and compatibility are the leading factors. A process node with a predetermined FinFET or MOSFET process dimension is then selected, this feature allowing for a tailored approach in chip design with considerations to factors such as chip density and power consumption. The predetermined process dimensions define specific physical characteristics related to the size of the transistors, which directly affect an integrated circuit's performance and power consumption.

One embodiment further details the selection between the FinFET and MOSFET process. The FinFET process, known for its 3D structure, reduces leakage current and allows for significant downscaling of the transistor size. This results in greater power efficiency and improved performance even at lower voltage levels, making it a preferred choice in high-performance applications such as server processors, high-end smartphones, and high-speed communication devices. On the other hand, the MOSFET process, which is based on silicon technology, is easier and cheaper to manufacture. It is usually chosen for applications where cost and compatibility with older technologies are significant factors-such as in consumer electronics, power supplies, and amplifiers. This component of one embodiment revolutionizes customization in chip-making, offering flexibility and optimization to manufacturers and developers.

Depending on the performance requirement, power consumption, and cost parameters of an application, the system can choose the optimal process node. This predetermined dimension can range from larger process nodes used for lower-cost, low-performance applications to smaller nodes used in high-performance, high-cost applications. The selection of process nodes and transistor dimensions plays a critical part in determining the functionality of the integrated circuit, thereby making one embodiment highly adaptable and scalable. This feature empowers chip designers with unlimited flexibility, reducing time, and development cost significantly.

The present one embodiment pertains to a unique system and method for determining analog circuit functionality based upon predefined templates. One embodiment provides a programmable logic system that utilizes a structured process to simplify, optimize, and automate the design and construction of offerings such as radio frequency (RF), analog, and mixed-signal circuits. The system is capable of discerning an appropriate category for a given circuit and can implement the functional elements of the associated hardware dependent on the specifics of the selected template.

The templating code operates by selecting a specific category (RF, analog, or mixed-signal) based on the predefined templates. It then narrows down to a specific circuit within the chosen category. This innovative aspect of one embodiment takes the guesswork out of designing complex circuits, simplifying matters for the designer, while ensuring optimal performance of the final output. The predefined templates are comprehensive and versatile, spanning a wide range of design and circuitry possibilities, allowing for large-scale customization and flexibility in the design process. The embedded selection of suitable architecture during the design process further makes this embodiment efficient and user-friendly.

One embodiment further allows for enhanced performance and functionality by determining the most suitable architecture for the identified specific circuit. This aspect of one embodiment provides the means for creating a highly efficient and effective circuit design that is both practical and functional for its intended purpose. The integration of the selection of suitable architecture ensures that the final design is not only operational but superior in its performance. By codifying circuit design knowledge into a easy-to-use, automated system, this one embodiment revolutionizes analog and mixed-signal design, delivering an efficient design process that reduces error and accelerates design time. Its broad applicability and beneficial contributions to the field make it a significant improvement within the field of circuit design.

One embodiment provides a deep learning engine that synthesizes analog cell design and analog module design utilizing non-volatile memory technology, in accordance with predefined design specifications, requirements, and parameters. Such a system is a formidable solution to the complex challenge involving the creation and optimization of analog circuit layouts. The system employs machine-based learning algorithms to analyze given design specifications alongside the blueprint of analog standard cells and modules, to synthesize the most efficient analog layout realization meeting the predefined requirements.

The system utilizes a deep learning model that is trained on vast datasets, containing various configurations of analog cell design and analog module design. The learning engine effectively learns the optimal patterns for synthesizing the analog layout and applies this knowledge while working on new or unique inputs. The deep learning engine is provided with the design specifications, the analog standard cell, and analog modules at the commencement of the process. These inputs guide the system in synthesizing the analog layouts in accordance with the predetermined parameters and requirements. As a result, the system enhances the optimization and efficiency of integrated circuits making it very valuable in designing chips for electronics and embedded systems.

In detail, the process starts with the system receiving inputs, i.e., the design specifications along with the analog standard cell and analog modules. The deep learning engine processes these inputs and synthesizes an analog layout realization. This synthesized layout is strictly in line with the predefined requirements and parameters, ensuring stringent quality control. Throughout the process, the system constantly learns and adapts, improving its efficiency and precision over time. The application of deep learning algorithms in synthesizing analog layout realization reduces erroneous outputs, saves time, and significantly improves the overall efficiency of analog circuit design processes.

The learning machine module is trained with various stages in data preparation and model construction processes. Firstly, data acquisition involves collecting raw data from various sources. This raw data may be structured or unstructured, depending on the source and type of data. The parameter selection step focuses on identifying significant parameters or features in the collected data that can improve the performance of the machine learning model. The data wrangling phase involves cleaning, standardizing, and transforming raw data into a format that can be easily used by machine learning algorithms.

Subsequent to initial data processing, the data analysis phase allows for a comprehensive understanding of the data's characteristics, relationships, and patterns, using statistical tools and methodologies. This lays the groundwork for the model development phase, wherein appropriate machine learning algorithms are chosen and applied to build the predictive or analytical model. Model training involves feeding processed and analyzed data to the learning machine module to learn from it and fine-tune the model parameters. The model verification step ensures that the model's predictions or analysis is accurate, robust, and reliable. Various techniques such as cross-validation, precision-recall trade-off, and ROC curve analysis might be used to determine the model's efficacy and reliability.

Upon model verification, the model is then deployed. The model deployment phase involves applying the trained machine learning model to real-world or unseen data to make predictions or decisions. The model continues to be monitored for performance and updated as necessary, ensuring it remains effective in the light of evolving data patterns and needs. The fine-tuning phase represents an ongoing process where the model's performance is continuously enhanced by tuning its parameters, updating training data, or even changing the whole machine learning algorithm in response to changing trends and objectives. This comprehensive system offers an end-to-end solution for the application of machine learning, thereby enhancing the performance and outcomes in various data-related tasks and applications.

The optimizer code is designed to receive several key layout parameters. They include matching, symmetry, current density, noise coupling, dummy insertion, guardring insertion, parasitic resistance, parasitic capacitance, and area margin. These parameters significantly influence the performance attributes of an IC. By being able to manipulate and optimize these parameters, the system ensures refined design modifications that lead to the optimal achievement of targeted performance objectives. The purpose of the optimization process is not just to simultaneously optimize multiple performance attributes, but also to adjust the parameters based on dynamic changes in the IC's operational environment.

One embodiment further encompasses methods for the refinement of the parameters. The optimization code can reduce or increase parameters like dummy insertion and guardring insertion to balance the parasitic resistance and capacitance. This results in minimizing noise coupling and maintaining current density. In addition, the inventive optimizer code ensures the symmetry and matching of the design, leading to lesser variations in output and increased yield. A unique feature of this one embodiment is that it provides an area margin for optimization, allowing designers to further refine the IC layout while still maintaining the constraints of the design. Consequently, one embodiment significantly enhances the reliability and predictability of IC performance, thereby ensuring cost-effective completion of IC projects.

Another embodiment pertains to a streamlined and adaptive system that combines simulation programs and yield analysis code to receive and analyze diverse Statistical Models. These models encompass a wide selection of engineering and mathematical applications, including Monte-Carlo models, Design for Manufacture (DFM) models, and predictive aging and self-heating models. This versatile collection of models enables the system to accommodate an array of scientific and industrial requirements, thereby enhancing the generation of complex and accurate simulations under different circumstances or operational constraints.

The deep learning engine iteratively collaborates with the yield analysis code, navigating through millions of permutations before zeroing in on the most optimal system configuration or layout. Working in conjunction with the deep learning engine is the optimizer code, which iteratively refines layout realization outcomes. The optimizer code is computed after each simulation, optimizing the system's functions based on feedback from the deep learning engine and the statistical data gathered. This synchronization guarantees incremental adaptations for high-quality decision-making, facilitating a continuous feedback loop. The culmination of this collaborative filtering process results in a final layout realization, embodying the optimized version of design derived from the amalgamation of different models, deep learning computations, and iterative optimization procedures. The ultimate objective is to ensure robust design, better operational efficiency and overall improvement in system performance.

The yield analysis can create a range of options from the final layout realization, productively leading to desired outcomes. These options include best yield, optimal performance, minimum power consumption, and minimum area-all of which are the key elements of any operational pipeline in electronics, semiconductors, and associated sectors. In this regard, the present system establishes an analytical platform that not only integrates inherent functionalities of conventional systems but also adopts novel techniques to enhance the yield analysis process. The system works by obtaining input data related to circuit design, material specification, production parameters, and many other related components, and then processes this data to generate a set of potential results. Thus, the present one embodiment is ideal for industries that require continuous optimization such as electronics manufacturing or semiconductor production. Unlike existing systems, this proposed one embodiment ensures the full array of results, from best yield to minimum area, all backed with accurate data analysis.

Additionally, the present one embodiment fosters efficiency by focusing on optimal performance and minimum power consumption. This concentration on energy efficiency is of considerable importance in modern electronic design and manufacturing. Through sophisticated mapping and correlations, the system serves to identify the patterns and regions of high efficiency, allowing for more energy-efficient designs and processes. Moreover, this one embodiment doesn't just stop at providing results; it also delivers comprehensive data detailing how each option could potentially affect the overall efficiency, performance, and sustainability of a design or a system.

The technology database is a vital part of one embodiment that stores specific information about the process technology used. This information may incorporate factors such as the technology nodes, dimensions, layer structures, et cetera. The system's ability to save iterative feedback into this database allows for the dynamic adjustment of the technology related-information, thereby improving the synthesis process over time. Furthermore, the template database stores reusable design templates. With the input from layout realizations, this database can be regularly updated with efficient and accurate design templates. The progressive improvement leads to faster turnaround times and better quality of synthesized layouts.

The standard cell module database stores the information regarding the standard cell modules or the building block of an integrated circuit. Saving iterative feedback in this database allows for enhancements and optimizations of the standard cells used. This database may comprise various types of cells, such as combinatorial logic cells, memory cells, or input and output cells. Each time a layout is realized, it provides valuable feedback that is stored and utilized in subsequent operations, leading to continuous improvement in the synthesized layouts. The presented system for an iterative feedback mechanism significantly innovates the electronic design synthesis process, saving time, improving accuracy, and enhancing overall efficiency.

The databases involved in the process are continually enriched. This is achieved by learning from previous syntheses, enhancing the overall system's efficiency and exactness with each synthesis. The system's capacity to progressively learn and evolve ensures that with each design cycle, data gathered from prior layouts is leveraged to improve current and future layout implementations. This ability to seamlessly integrate past experiences into present operations sets this technology apart from conventional layout strategies, paving the way for an increasingly accurate and efficient electronic circuit design experience.

This automatic layout synthesis process reduces the typical laborious manual iteration process when evaluating and addressing signal integrity issues. By automating this process, the system not only reduces the time and effort required for layout development but also significantly diminishes the chance of human-induced errors. This innovative approach provides an optimal combination of time efficiency, error reduction, and yield optimization, making it an invaluable tool in the current and future landscape of electronic design automation.

The pre-trained Deep Learning engine is applied to synthesis. Past design specifications and analog standard cells and modules are used as input data to this engine which learns and makes predictions about optimizing analog layout designs based on this training. The generated layouts are optimized and refined based on user-defined parameters. This involves fine-tuning of the analog or mixed-mode layout realization to meet specific needs, improve circuit performance and minimize the power consumption and area. In addition, the method simulates the yield of the analog or mixed mode layout realization using statistical modeling. This step allows the prediction of the impact of variability on circuit performance. It enables optimization and adjustments of parameters to obtain desired performance characteristics.

The method then enables the selection of a final layout realization from a range of options considering yield, performance, or power options. This function empowers users to make informed choices best suited to their individual requirements. The analog or mixed-mode layout realization feedback is routed back into the technology database, the template database and the analog standard cell or module database. This feedback improves the efficiency and refinement of these databases, continually emphasizing on learning and getting updated with fresh realizations, thus ensuring the machine learning model stay relevant and accurate to the latest specifications and updating design specification and process technology for further enhancement.

In one embodiment, an appropriate process node with predetermined dimensions for the chosen FinFET process or the MOSFET process. This selection process can be guided by a number of determinants such as the anticipated current flow, the required device density and the determination to minimize leakage currents. Design techniques, such as the use of smallest possible feature sizes, can be utilized here to maximize the integration level of the selected technology. Predetermined dimensions are typically set by industry standards and this method leverages the named standards to ensure compatibility and interoperability with other devices.

The disclosed method provides a systematic approach for the selection of specific technologies and process nodes in the production of semiconductor devices. This semi-automated technique expedites the decision-making process allowing for quicker manufacturing turns and a more efficient transit through the product development cycle. Furthermore, predetermining the dimensions of the selected process node derivates standardization and forethought into the fabrication process. The resultant devices manufactured in accordance with the method presented are therefore poised with the advantage of optimized performance and high integration density. Thus, this method provides substantial improvements in terms of operational efficiency, cost-effectiveness, and product quality in the field of semiconductor device manufacturing processes.

In another implementation, the methodology engages in a sequence of step selections: First, it categorizes the circuit designs as RF, Analog, or Mixed-Signal-thereby determining the overall nature and scope of the design. Secondly, the method involves the selection of a specific circuit within the selected category. This enables the design process to be precise, tailored, and optimally adapted to the specific circuitry needs. Once a particular circuit is chosen, the method goes on to the third step. It elects a suitable architecture for the chosen circuit design. The compatibility and congruity between circuit types and their appropriate architectures play a significant role in achieving the desired functionality and performance for the finished circuit.

In one implementation, the optimization process refines the design and realization of ICs by manipulating and employing a variety of layout parameters, which include but are not limited to: matching, symmetry, current density, noise coupling, dummy insertion, guardring insertion, parasitic resistance, parasitic capacitance, and area margin. During the optimizing process, these parameters are examined and adjusted to achieve an optimal realization of the IC's design. Matching and symmetry are used to improve the performance of circuit components, whilst the parameter of current density manages power efficiency. Noise coupling and the insertion points of dummy fill and guardring lay major emphasis on reliability and integrity of the IC, setting a check on unwanted signals or interference. Likewise, the factors of parasitic resistance and parasitic capacitance are effectively optimized to consider signal delay and power consumption. Lastly, the parameter of area margin is adjusted to ensure optimal space management on the silicon chip; that is, how much vacant space should there be to facilitate heat dissipation, space for wiring, and room for additional components or revisions.

One embodiment integrates various statistical models-Monte-Carlo model, Design for Manufacture (DFM) model, aging and self-heating models into a comprehensive system. These statistically derived models are then provided to the yield analysis step. In this context, the yield analysis refers to the estimation of a method's ability to produce a defect-free product, ideally aiming for a one hundred percent yield rate wherein every product is free of defects. The yield analysis integrates crucial information about the manufacturing process, quality control steps, assembly and testing procedures for subsequent considerations during the manufacturing phase. This approach allows for the analyses of potential defects in early stages in order to rectify it sooner, thereby improving overall manufacturing yield. The yield analysis and the deep learning engine collaboratively process a large amount of collected data to predict and optimize the performance, ensuring that the result is the best possible layout realization. The deep learning engine can learn independently and identify hidden patterns in various data sets. It uses complex algorithms to construct models capable of making informed predictions and decisions automatically. This intelligent design and analysis approach ensures a tangible improvement in overall yield rate and manufacturing process efficiency.

The optimization process is highly dynamic and iterative, responding to insights from the statistical models and the deep learning engine. Using parameters from the yield analysis, it cycles through different layout realizations, comparing and evaluating each one to find the optimal realization against the set goals. This optimizing procedure aims to adaptively refine and perfect the manufacturing layout design until the desired efficient and optimal configuration is accomplished, which significantly enhances the yield rate and quality of the manufacturing process. One embodiment involves the assessment of various parameters including but not limited to yield, performance, power consumption and area. The distinctive feature of one embodiment is the ability to offer a range of options based on these parameters post the yield analysis. Yield is broadly understood as the quantity of semiconductors that are efficiently produced without defects. This analysis is crucial in assessing the profitability and success rate of the production process. Performance, as a parameter, assesses how well this device can execute its tasks or operations, influencing the overall efficiency of the final product. Similarly, power consumption is the electrical power used by the semiconductor device for its operations. A lower power consumption is often desirable, since it ensures sustainability and cost-effectiveness. The area parameter, on the other hand, refers to the physical dimensions or footprint of the designed semiconductor device. The balance between these parameters can critically influence the final design and suitability of its application.

One embodiment affords flexibility to the designers by presenting a range of optimized design choices, each representing a different combination of yield, performance, power consumption and area parameters. The balance between these parameters can lead to different final layout realizations. This method allows for a more efficient, nuanced and balanced approach for semiconductor device design, providing a competitive edge in the fast-evolving industry. Through such robustness and versatility, one embodiment serves to augment the process of semiconductor production with environmental and economic advantages. Therefore, this innovation represents a significant advancement in yield analysis and semiconductor device design methodology.

The method involves integrating final layout realization(s) as feedback into a technology database, a template database, and a standard cell module database. This process is unique as it pertains to a cyclical methodology wherein feedback from final layout realizations is provided back to the aforementioned databases. The purpose of implementing these feedback mechanisms is to enrich the overall data resources and improve the subsequent outcomes. Specifically, when the final layout of a design is fed back into the databases, it provides additional empirical data that extends the existing knowledge within these storage units. This facilitates in formulating more optimal project outcomes in the future. An iterative, continuous learning system is thus achieved that enhances each database during operation. Each database harvests and leverages structured information collected from the final layout realizations to continually expand, improve and refine its corresponding data sets. At the same time, the technology and template databases, in conjunction with the standard cell module database, make use of these enriched repositories to craft higher quality and more effective synthesis processes. Through this mutually beneficial relationship, the method promotes elevated efficiency in future project endeavors.

In the same sense, the method brings about improved accuracy in each subsequent synthesis process. The innovative aspect of one embodiment lies in utilizing the outcome of each synthesis, the final layout, as a learning point for the databases, which are essentially the starting points of the synthesis processes. By continually updating these databases with feedback from real-world applications, the likelihood of errors is reduced, the design process is optimized and the reliability of the synthesis results is increased. This intelligent, self-learning and error-correcting method is a leap forward in achieving consistent excellence in the product development cycle.

By utilizing detailed and systematic steps of data acquisition, parameter selection, data wrangling, Data Analysis, Develop Model, Train Model, Model Verification, Deployment, Monitoring and Fine-tuning the results, the system is designed to ensure that the deep learning engine operates at maximum efficiency, accuracy and effectiveness. The data acquisition step involves collecting relevant and high-quality data from credible and reliable sources. This data serves as the foundation for the learning process of the deep learning engine. The parameter selection involves selecting relevant parameters for the deep learning process to use; these parameters may include variables such as time, location, numeracy, etc., based on the objective at hand.

One implementation encompasses data wrangling, a process that involves cleaning, structuring and enriching raw data into a desired format for better decision making in less time. This is followed by data analysis which involves examining, cleaning, transforming, and modelling data with the goal of discovering useful information and aiding in decision-making. The development and training of the model are integral steps where the algorithm learns from the data provided. It involves building an effective model using the input and output data, and then using this model to train the deep learning engine for it to be able to make accurate predictions. The model verification is then executed to validate the model's efficiency and effectiveness.

Deployment refers to making the model available to stakeholders—it's the bringing of the trained deep learning engine into operation. Monitoring step involves continuous tracking of the performance of the strategy to make sure that it remains relevant and effective. Lastly, Fine-tuning is carried out to enhance the performance of the model by continuously refining parameters based on the intake of new data and performance feedback. Such an innovative method as described here provides a robust, holistic, and methodological approach to training a deep learning engine, offering significant improvements over traditional techniques. It allows for continuous development and adjusts to dynamic variables, upgrading performance and results, and suits an expanding scope of applications across various sectors.

An additional aspect of one embodiment includes enriching databases for enhanced efficiency and accuracy with each subsequent synthesis. This feature allows the method to continuously learn from each synthesis procedure, further optimizing and refining the design process for future iterations. The accumulated design knowledge enhances the predictive accuracy of the method, thus reducing the error rate. This feature also promotes effective reuse of design resources, where successful designs are retained and used as benchmarks for future designs. Consequently, this dramatically improves the efficiency and consistency of the design process, leading to a more reliable and high-quality IC layout design.

The system can apply a variety of Rule Checks on an analog or mixed-mode layout realization. This iterative and systematic method primarily includes the application of Design Rule Check (DRC), Layout versus Schematic (LVS), Electrical Rule Check (ERC), Antenna Rule Check (ANT), Electrostatic Discharge check (ESD), and Latch-up rule check. Each of these checks plays a critical role in identifying potential design issues in the analog or mixed-mode layout realization, thereby providing a comprehensive check and balance mechanism during the manufacturing process in the semiconductor industry.

The Design Rule Check (DRC) functions as an algorithmic suite that checks the design of the layout for alignment with the fabrication constraints. The DRC identifies potential violations that might cause problems during fabrication, such as insufficient spacing or too-thin metal lines. The Layout versus Schematic (LVS) is a physical verification method that ensures the consistency of the layout design against the circuit schematic. It checks whether the connectivity and topology of the analog or mixed-mode layout match with the schematic. In contrast, the Electrical Rule Check (ERC) monitors for electrical continuity, undesired resistance levels, and other potential electrical issues.

The Antenna Rule Check (ANT) is designed to identify areas that could potentially suffer from antenna effects, i.e., charge build-up during fabrication that may damage thin gate oxide. The Electrostatic Discharge Check (ESD) verifies the existence and correctness of ESD protection circuit in the layout. The Latch-up rule check focuses on preventing the unwanted latching condition arising from the parasitic thyristor structure in CMOS technology. By combining these checks, the disclosed method provides a comprehensive tool to ensure optimal performance and functionality for the analog or mixed-mode layout realization, reducing manufacturing errors and enhancing overall efficiency.

Various modifications and alterations of the invention will become apparent to those skilled in the art without departing from the spirit and scope of the invention, which is defined by the accompanying claims. It should be noted that steps recited in any method claims below do not necessarily need to be performed in the order that they are recited. Those of ordinary skill in the art will recognize variations in performing the steps from the order in which they are recited. In addition, the lack of mention or discussion of a feature, step, or component provides the basis for claims where the absent feature or component is excluded by way of a proviso or similar claim language.

While various embodiments of the present invention have been described above, it should be understood that they have been presented by way of example only, and not of limitation. The various diagrams may depict an example architectural or other configuration for the invention, which is done to aid in understanding the features and functionality that may be included in the invention. The invention is not restricted to the illustrated example architectures or configurations, but the desired features may be implemented using a variety of alternative architectures and configurations. Indeed, it will be apparent to one of skill in the art how alternative functional, logical or physical partitioning and configurations may be implemented to implement the desired features of the present invention. Also, a multitude of different constituent module names other than those depicted herein may be applied to the various partitions. Additionally, with regard to flow diagrams, operational descriptions and method claims, the order in which the steps are presented herein shall not mandate that various embodiments be implemented to perform the recited functionality in the same order unless the context dictates otherwise.

Although the invention is described above in terms of various exemplary embodiments and implementations, it should be understood that the various features, aspects and functionality described in one or more of the individual embodiments are not limited in their applicability to the particular embodiment with which they are described, but instead may be applied, alone or in various combinations, to one or more of the other embodiments of the invention, whether or not such embodiments are described and whether or not such features are presented as being a part of a described embodiment. Thus the breadth and scope of the present invention should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the such as; the term “example” is used to provide exemplary instances of the item in discussion, not an exhaustive or limiting list thereof; the terms “a” or “an” should be read as meaning “at least one,” “one or more” or the such as; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Hence, where this document refers to technologies that would be apparent or known to one of ordinary skill in the art, such technologies encompass those apparent or known to the skilled artisan now or at any time in the future.

A group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise. Furthermore, although items, elements or components of the invention may be described or claimed in the singular, the plural is contemplated to be within the scope thereof unless limitation to the singular is explicitly stated.

The presence of broadening words and phrases such as “one or more,” “at least,” “but not limited to” or other such as phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, may be combined in a single package or separately maintained and may further be distributed across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives may be implemented without confinement to the illustrated examples. For example, block diagrams and their accompanying description should not be construed as mandating a particular architecture or configuration.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A system to synthesize an analog or mixed-signal circuit layout, comprising:
a pre-defined fabrication technology database, categorized by FinFET or MOSFET;
code for selecting a specific technology from the pre-defined technology database;
a pre-defined template database, categorized by various analog circuitry functionality;
code for templating a specific circuit template from the pre-defined template database;
a pre-trained deep learning engine to synthesize the analog or mixed-signal circuit layout based on existing design specifications and analog standard cell and analog modules;
an optimizer code to refine the analog or mixed-signal circuit layout given user-defined layout parameters;
code for simulating a yield analysis for the analog or mixed-signal circuit layout given one or more statistical models;
an analog or mixed-signal circuit layout generator that considers yield, performance, or power option; and
code for feeding the analog or mixed-signal circuit layout back to the technology database, template database and analog standard cell module database to improve layout efficiency and accuracy.

2. The system of claim 1, wherein code for selecting the specific technology first selects a FinFET process or a MOSFET process, and then selects a process node with a predetermined FinFET or MOSFET process dimension.

3. The system of claim 1, wherein the templating code determines analog circuit functionality based on one or more predefined templates, wherein the templating code selects radio frequency (RF), analog, or mixed-signal category, and wherein the templating code further selects a specific circuit, and then selects a suitable architecture.

4. The system of claim 1, wherein the design specifications and the analog standard cell and analog modules are provided to the deep learning engine to synthesize an analog layout realization in accordance with the specified requirements and parameters.

5. The system of claim 1, wherein the learning machine module is trained with data acquisition, parameter selection, data wrangling, data analysis, model development, model training, model verification, and model deployment, monitoring and fine-tuning.

6. The system of claim 1, wherein the optimizer code receives layout parameters, including matching, symmetry, current density, noise coupling, dummy insertion, guardring insertion, parasitic resistance, parasitic capacitance, area margin to refine and achieve an optimal realization.

7. The system of claim 1, wherein simulating and yield analysis code receives Statistical Models, including Monte-Carlo model, Design for Manufacture (DFM) model, aging and self-heating models, and collaborates with the deep learning engine and the optimizer code iteratively to derive a final layout realization.

8. The system of claim 1, wherein the yield analysis presents a range of options from a final layout realization, following the yield analysis procedure, including best yield, optimal performance, minimum power consumption and minimum area.

9. The system of claim 1, wherein iterative feedbacks from final layout realizations are saved in the technology database, the template database and the standard cell module database to enhance efficiency and accuracy in subsequent synthesis operations.

10. The system of claim 1, wherein the synthesized layout implementation meets user-defined signal integrity requirements, attains optimal yield, mitigating human error, and concurrently minimizes overall layout development time and iteration effort, further comprising enriching the databases for enhanced efficiency and accuracy with each synthesis.

11. A method of analog layout synthesis with Machine Learning (ML), comprising:
a. selecting a specific technology from a pre-defined technology database, categorized by FinFET or MOSFET;
b. templating a specific circuit template from a pre-defined Template Database, categorized by various analog circuitry functionality;
c. applying a pre-trained Deep Learning engine to synthesis analog layout based on existing design specifications, analog standard cell and analog modules;
d. optimizing and refining an analog or mixed-mode layout realization given user-defined layout parameters;
e. simulating and analyzing a yield of the analog or mixed-mode layout realization given statistical models;
f. generating an analog or mixed-mode layout realization with a range of options including yield, performance, or power option; and
g. feeding the analog or mixed-mode layout realization back to the technology database, template database and analog standard cell/module database for further efficiency and accuracy refinement.

12. The method of claim 11, wherein selecting the specific technology first selects a FinFET process or a MOSFET process, and then selects a process node with predetermined dimensions for the FinFET process or the MOSFET process.

13. The method of claim 11, wherein the templating step determines analog circuit functionality based on one or more predefined templates, selects Radio Frequency (RF), Analog, or Mixed-Signal category, selects a specific circuit, and then selects a suitable architecture.

14. The method of claim 11, comprising applying the pre-trained deep learning engine to process the design specifications and the analog standard cell and analog modules to synthesize the analog or mixed-mode layout realization in accordance with the specified requirements and parameters.

15. The method of claim 11, wherein the optimizing comprises using layout parameters, including matching, symmetry, current density, noise coupling, dummy insertion, guardring insertion, parasitic resistance, parasitic capacitance, area margin to refine and achieve an optimal realization.

16. The method of claim 11, wherein Statistical Models, including Monte-Carlo model, Design for Manufacture (DFM) model, aging and self-heating models, are integrated and provided to the yield analysis step and wherein the yield analysis collaborates with the deep learning engine, and wherein the optimizing step iteratively derives a final layout realization.

17. The method of claim 11, wherein the final layout realizations, following the yield analysis, presents a range of options, including yield, performance, power consumption and area parameters.

18. The method of claim 11, comprising providing the final layout realizations as feedback into the technology database, the template database, and the standard cell module database. This iterative process enriches the databases, contributing to enhanced efficiency and accuracy in subsequent synthesis endeavors.

19. The method of claim 11, comprising training the deep learning engine with data acquisition, parameter selection, data wrangling, Data Analysis, Develop Model, Train Model, Model Verification, Deployment, Monitoring and Fine-tuning.

20. The method of claim 11, comprising applying Rule Checks to the analog or mixed-mode layout realization including Design Rule Check (DRC), Layout versus Schematic (LVS), Electrical Rule Check (ERC), Antenna Rule Check (ANT), Electrostatic Discharge check (ESD) and Latch-up rule check.
